(19) United States
(12) Patent Application Publication
(10) Pub. No.: US 2015/0357277 A1
(43) Pub. Date: Dec. 10, 2015

(54) WIRING SUBSTRATE

(71) Applicant: NGK SPARK PLUG CO., LTD., Nagoya-shi, Aichi (JP)

(72) Inventors: Makoto NAGAI, Komaki-shi (JP); Seiji MORI, Kounan-shi (JP); Tatsuya ITO, Kakamigahara-shi (JP); Takahiro HAYASHI, Chino-shi (JP)

(21) Appl. No.: 14/762,185

(22) PCT Filed: Dec. 12, 2013
(86) PCT No.: PCT/JP2013/007314

§ 371 Date: Jul. 20, 2015

(30) Foreign Application Priority Data
Mar. 26, 2013 (JP) 2013-063369

(51) Int. Cl. H01L 23/498; H01L 23/544

(52) U.S. Cl. CPC H01L 23/49838; H01L 23/49816; H01L 23/49822; H01L 23/544; H01L 2223/54426

(57) ABSTRACT

To provide a wiring substrate which can reliably prevent progress of cracking in a solder bump, and which exhibits improved reliability. The wiring substrate 10 of the present invention includes a substrate main body 11, pads 61, and a solder resist 81. The pads 61 are provided on the substrate back surface 13 of the substrate main body, and have surfaces 62 on which solder bumps 84 employed for connection of a motherboard 91 can be formed. The solder resist 81 covers the substrate back surface 13 of the substrate main body, and has openings 82 through which the pads 61 are exposed. A protrusion 71 is formed on a portion of the surface 62 of each pad 61. The height A4 of the end surface 72 of the protrusion 71, as measured from the surface 62 of the pad 61, is smaller than the depth of each opening 82. The protrusion 71 is provided in the opening 82 such that the peripheral surface 73 of the protrusion 71 faces the inner surface of the opening 82, and the protrusion 71 has a plan-view shape similar to that of the opening 82.

### TECHNICAL FIELD

The present invention relates to a wiring substrate having, on a substrate back surface thereof, a plurality of pads on which solder bumps employed for connection of a motherboard can be formed.

### BACKGROUND ART

In recent years, semiconductor integrated circuit elements (IC chips) used as microprocessors of computers or the like have been increasingly required to have higher speed and higher performance. In association therewith, IC chips tend to have an increased number of terminals and a reduced inter-terminal pitch. In general, a large number of terminals are densely disposed in an array form on the bottom surface of an IC chip. Such a group of terminals are flip-chip connected to a group of terminals on a motherboard. However, since the inter-terminal pitch differs greatly between the IC-chip-side terminal group and the motherboard-side terminal group, difficultly is encountered in connecting the IC chip directly onto the motherboard. Therefore, generally, there is employed a technique in which a semiconductor package including an IC chip mounted on a wiring substrate is fabricated, and the semiconductor package is mounted on a motherboard (see, for example, Patent Documents 1 and 2). In connection therewith, there has been proposed a wiring substrate having a structure for achieving electrical connection to a motherboard, wherein a plurality of pads are disposed on the substrate back surface of the wiring substrate, and solder bumps (so-called BGA bumps) are formed on the pads.

Now will be described an example of the aforementioned conventional wiring substrate. As shown in FIG. 8, a wiring substrate 101 of this type has a solder resist 103 formed so as to cover the substrate back surface 102 of the substrate, and the solder resist 103 has a plurality of openings 105 through which pads 104 are exposed. A solder bump 106 is formed in each of the openings 105. The solder bump 106 is formed through, for example, the printing method or the solder ball method (micro-ball method). The printing method is a technique in which a solder paste is applied through printing, by means of a metal mask, onto each of the pads 104 formed on the substrate back surface 102 of the wiring substrate 101, followed by heat-melting (reflow), to thereby form the solder bump 106. The solder ball method is a technique in which a solder ball is placed on each of the pads 104 and reflowed, to thereby form the solder bump 106.

### PRIOR ART DOCUMENT

### Patent Document

Patent Document 1: Japanese Patent Application Laid-Open (kokai) No. 2004-95864 (e.g., FIG. 1)
Patent Document 2: Japanese Patent No. 4502690 (e.g., FIG. 4)

### SUMMARY OF THE INVENTION

### Problems to be Solved by the Invention

However, in the case where the wiring substrate 101 is mounted on a motherboard, when stress is generated due to, for example, thermal cycles (heating and cooling) in association with reflow of a solder ball, the stress may concentrate at the edge of each opening 105, resulting in occurrence of cracking 107 in the solder bump 106. This cracking 107 tends to proceed along the interface between the solder bump 106 and the pad 104, which may cause breakage of an electrical path formed of the solder bump 106. Therefore, the thus-produced wiring substrate 101 may be regarded as defective; i.e., the reliability of the wiring substrate 101 may be lowered.

In view of the foregoing, an object of the present invention is to provide a wiring substrate which can reliably prevent progress of cracking in a solder bump, and which exhibits improved reliability.

### Means for Solving the Problems

One means for solving the aforementioned problems (means 1) is a wiring substrate comprising a substrate main body having a substrate main surface and a substrate back surface; a plurality of pads provided on the substrate back surface of the substrate main body, and having surfaces on which solder bumps employed for connection of the wiring substrate to a motherboard can be formed; and a solder resist covering the substrate back surface of the substrate main body, and having a plurality of openings through which the pads are exposed, the wiring substrate being characterized in that each of the pads has, on a portion of the surface thereof, a protrusion having an end surface and a peripheral surface; the end surface of the protrusion has a height as measured from the surface of the pad, the height being smaller than the depth of each of the openings; the protrusion is provided in the opening such that the peripheral surface faces an inner surface of the opening; and the protrusion has a plan-view shape similar to that of the opening.

Thus, according to the wiring substrate of means 1, even if cracking occurs in a solder bump, and the cracking proceeds along the interface between the solder bump and the corresponding pad, progress of the cracking is reliably suppressed when it reaches the protrusion. Therefore, breakage of an electrical path formed of the solder bump can be prevented, and the thus-produced wiring substrate exhibits improved reliability.

No particular limitation is imposed on the type of the substrate main body forming the wiring substrate, and the substrate main body may be formed of, for example, a resin. The resin-made substrate main body may be a substrate main body formed of, for example, an EP resin (epoxy resin), a PI resin (polyimide resin), a BT resin (bismaleimide-triazine resin), or a PPE resin (polyphenylene ether resin). Alternatively, the substrate main body may be formed of a composite material containing such a resin and glass fiber (woven glass fabric or non-woven glass fabric). Alternatively, the substrate main body may be formed of a composite material containing such a resin and an organic fiber (e.g., polyamide fiber). Alternatively, the substrate main body may be formed of a resin-resin composite material prepared by impregnating a three-dimensional net-like fluororesin base (e.g., continuous porous PTFE) with a thermosetting resin such as an epoxy resin. Alternatively, the substrate main body may be formed of, for example, any ceramic material. No particular limitation is imposed on the structure of the wiring substrate, and the wiring substrate may be, for example, a build-up multilayer wiring substrate including a core substrate and a build-up layer formed on one surface or both surfaces of the core substrate, or a coreless wiring substrate including no core substrate.

A plurality of pads forming the aforementioned wiring substrate are provided on the substrate back surface of the substrate main body. The pads may be formed of, for example, an electrically conductive metal material. Examples of the metal material employed for forming the pads include gold, silver, copper, iron, cobalt, and nickel. Particularly, the pads may be formed mainly of copper. In such a case, the pads exhibit reduced resistance and improved electrical conductivity, as compared with the case where the pads are formed mainly of a material other than copper. The pads are preferably formed through plating. In such a case, the pads can be formed uniformly with high accuracy. When the pads are formed through reflow of a metal paste, since difficulty is encountered in forming the pads uniformly with high accuracy, there may be a difference in height between individual pads.

The solder resist forming the aforementioned wiring substrate is formed of a resin having insulation property and heat resistance. The solder resist , which covers the back surface of the substrate main body, serves as a protective film for protecting the substrate back surface. Specific examples of the material of the solder resist include an epoxy resin and a polyimide resin. A plurality of openings provided in the solder resist may have, for example, a plan-view circular shape, a plan-view elliptical shape, a plan-view triangular shape, a plan-view rectangular shape, or a plan-view square shape.

The protrusion forming the aforementioned wiring substrate is provided on a portion of the surface of each pad. Examples of the material employed for forming the protrusion include copper, silver, iron, cobalt, and nickel. Particularly, the protrusion may be formed mainly of copper. In such a case, the protrusion exhibits reduced resistance and improved electrical conductivity, as compared with the case where the protrusion is formed mainly of a material other than copper. The protrusion may be formed mainly of the same electrically conductive material as that employed for forming the pads. In this case, formation of the protrusion does not require provision of a material different from that employed for forming the pads. Therefore, since the materials required for production of the wiring substrate can be reduced, the wiring substrate can be produced at low cost.

The height of the end surface of the protrusion, as measured from the surface of the pad, is smaller than the depth of the opening. The protrusion is provided in the opening such that the peripheral surface of the protrusion faces an inner surface of the opening. The protrusion has a plan-view shape similar to that of the opening. The protrusion may have, for example, a circular columnar shape, an elliptical shape, a circular columnar shape, a triangular columnar shape, a triangular pyramidal shape, a quadrangular columnar shape, a quadrangular pyramidal shape, or a spherical shape. The protrusion may have, for example, a plan-view circular shape, a plan-view elliptical shape, a plan-view triangular shape, or a plan-view rectangular shape. Both the protrusion and the opening, which have a similar plan-view shape, may have, for example, a plan-view circular shape, a plan-view elliptical shape, a plan-view triangular shape, or a plan-view rectangular shape. When both the protrusion and the opening have a shape having corners (e.g., a plan-view triangular shape or a plan-view rectangular shape); i.e., when the protrusion has a plurality of peripheral surfaces and the opening has the same number of inner surfaces as the number of the peripheral surfaces, preferably, the protrusion is provided in the opening such that the respective peripheral surfaces of the protrusion face the corresponding inner surfaces of the opening, and such that each peripheral surface is parallel to the facing inner surface.

Preferably, the protrusion is provided in the opening such that the peripheral surface of the protrusion is located near the inner surface of the opening. With this configuration, even when cracking occurs in a solder bump, the cracking reaches the protrusion rapidly, and thus progress of the cracking can be readily prevented. Preferably, the gap between the peripheral surface of the protrusion and the inner surface of the opening has fixed dimensions over the entire peripheral surface. With this configuration, even when cracking occurs at any portion of the periphery of a solder bump, the cracking reaches the protrusion rapidly, and thus progress of the cracking can be more reliably prevented. The protrusion may have a rounded edge between the end surface and the peripheral surface. With this configuration, even when stress is applied to a solder bump, concentration of the stress is suppressed at the edge between the end surface of the protrusion and the peripheral surface thereof, since the edge is rounded. Therefore, occurrence of cracking at the edge can be reliably prevented.

The protrusion may be formed through, for example, plating. When the protrusion has a columnar shape, the protrusion can be readily formed through plating. When, for example, the protrusion is formed mainly of copper, the protrusion may be formed through copper plating. In such a case, the protrusion exhibits improved electrical conductivity, as compared with the case where the protrusion is formed from, for example, an electrically conductive paste. Alternatively, the protrusion may be formed through, for example, the following method: a method in which an electrically conductive paste is applied through printing onto the pad; a method including only a step of applying an electrically conductive member onto the pad; or a method in which a plate material having electrical conductivity and having a size larger than that of the protrusion is applied onto the pad, and then the plate material is subjected to etching.

At least a portion of the surface of the pad, and the end surface and peripheral surface of the protrusion may be continuously covered with a plating layer. With this configuration, a solder is likely to adhere to the surface of the pad and the surfaces (end surface and peripheral surface) of the protrusion, and thus a solder bump can be reliably formed.

A plurality of protrusions may be provided on the side toward the substrate back surface of the substrate main body, and at least some of the protrusions may serve as an alignment mark. With this configuration, at least some of the protrusions can be effectively employed as alignment marks for alignment of parts or the like. Also in this case, alignment can be carried out with respect to the edge of an opening of the solder resist , or with respect to the periphery of a protrusion (i.e., the edge between the end surface and peripheral surface of the protrusion). Since a protrusion serving as an alignment mark can be formed through the same process as for forming a protrusion which does not serve as an alignment mark, the production cost for the wiring substrate can be reduced. The alignment mark may have a plan-view shape different from that of the protrusion for connection of a motherboard. With this configuration, the alignment mark can be readily recognized during alignment.

A solder bump employed for connection of a motherboard can be formed on the surface of each pad. No particular limitation is imposed on the solder material employed for forming the solder bump, and the solder material may be, for example, a tin-lead eutectic solder (Sn/37Pb, melting point: 183° C.). The solder material employed may be, for example, an Sn/Pb solder other than the tin-lead eutectic solder, such as a Sn/36Pb/2Ag solder (melting point: 190° C.). The solder material employed may be, instead of the aforementioned lead-containing solder, a lead-free solder such as an Sn—Ag solder, an Sn—Ag—Cu solder, an Sn—Ag—Bi solder, an Sn—Ag—Bi—Cu solder, an Sn—Zn solder, or an Sn—Zn—Bi solder.

A solder bump may be formed on the surface of a protrusion provided in at least one opening of the plurality of openings. With this configuration, even if cracking occurs in the solder bump, and the cracking proceeds along the interface between the solder bump and the corresponding pad, progress of the cracking is reliably suppressed when it reaches the protrusion. Therefore, breakage of an electrical path formed of the solder bump can be prevented, and the thus-produced wiring substrate exhibits improved reliability.

### BRIEF DESCRIPTION OF THE DRAWINGS

FIG. 1 is a schematic cross-sectional view of a wiring substrate according to one specific embodiment of the present invention.

FIG. 2 is a schematic plan view of the wiring substrate.

FIG. 3 is a cross-sectional view of a main portion of the wiring substrate, which shows a first pad and a first protrusion.

FIG. 4 is a cross-sectional view of a main portion of the wiring substrate, which shows a second pad and a second protrusion.

FIG. 5 illustrate a wiring substrate production method.

FIG. 6 illustrate the wiring substrate production method.

FIG. 7 illustrate the wiring substrate production method.

FIG. 8 is a cross-sectional view of a main portion of a conventional wiring substrate, which shows problems involved therein.

### MODES FOR CARRYING OUT THE INVENTION

One specific embodiment of the present invention will next be described in detail with reference to the drawings.

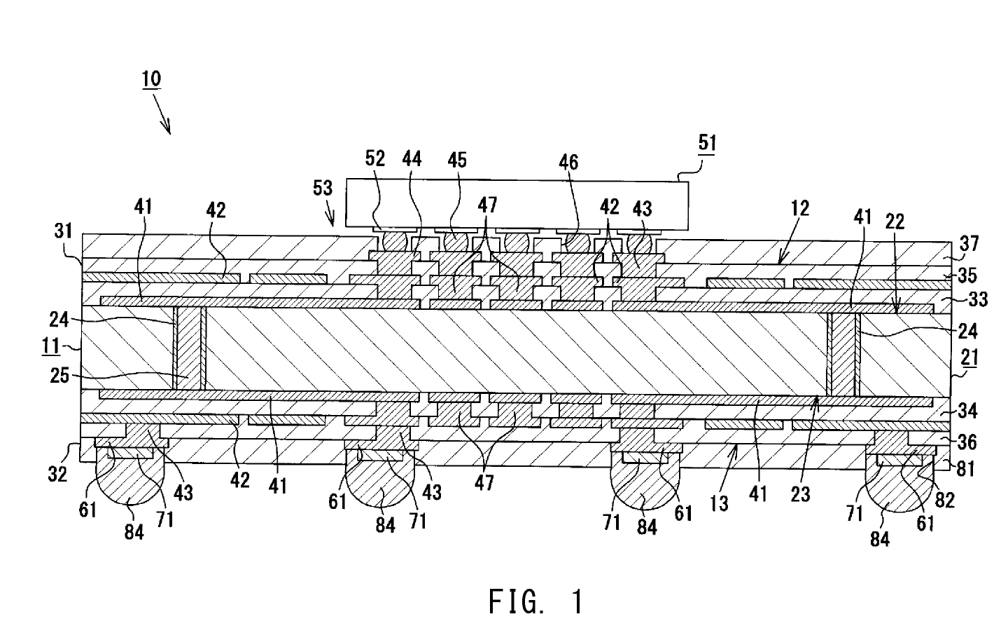

As shown in FIG. 1, a wiring substrate 10 of the present embodiment is an IC chip mounting wiring substrate. The wiring substrate 10 includes a generally rectangular plate-like substrate main body 11 having a substrate main surface 12 (upper surface in FIG. 1) and a substrate back surface 13 (lower surface in FIG. 1). The substrate main body 11 includes a generally rectangular plate-like core substrate 21; a main-surface-side build-up layer 31 formed on a core main surface 22 of the core substrate 21; and a back-surface-side build-up layer 32 formed on a core back surface 23 of the core substrate 21.

In the present embodiment, the plate-like core substrate 21 has a generally rectangular shape in plan view (length: 25 mm, width: 25 mm, thickness: 1.0 mm). The core substrate 21 exhibits a thermal expansion coefficient of 10 to 30 ppm/° C. (specifically 18 ppm/° C.) in a planar direction (X-Y direction). The thermal expansion coefficient of the core substrate 21 corresponds to the average of values as measured at 0° C. to glass transition temperature (Tg). A plurality of through hole conductors 24 are formed in the core substrate 21. The through hole conductors 24 electrically connect the core main surface 22 of the core substrate 21 with the core back surface 23 thereof. The interior of each through hole conductor 24 is filled with a blocking body 25 made of, for example, an epoxy resin. Copper conductor layers 41 are formed, through patterning, on the core main surface 22 of the core substrate 21 and on the core back surface 23 thereof, and the respective conductor layers 41 are electrically connected to the through hole conductors 24.

As shown in FIG. 1, the main-surface-side build-up layer 31 has a structure including two resin insulation layers 33 and 35 formed of a thermosetting resin (epoxy resin), and copper conductor layers 42, wherein the resin insulation layers 33 and 35 and the conductor layers 42 are alternately stacked. In the present embodiment, each of the resin insulation layers 33 and 35 exhibits a thermal expansion coefficient of about 10 to about 60 ppm/° C. (specifically about 30 ppm/° C.). The thermal expansion coefficient of the resin insulation layer 33 or 35 corresponds to the average of values as measured at 30° C. to glass transition temperature (Tg). A plurality of terminal pads 44 are formed on the resin insulation layer (second layer) 35 in an array pattern. Almost the entire main surface of the resin insulation layer 35 is covered with a solder resist 37. Openings 46 through which the terminal pads 44 are respectively exposed are provided at specific positions of the solder resist 37. A plurality of solder bumps 45 are provided on the terminal pads 44. The respective solder bumps 45 are electrically connected to surface connection terminals 52 of a rectangular flat plate-like IC chip 51. A region including the terminal pads 44 and the solder bumps 45 is an IC chip mounting region 53 on which the IC chip 51 can be mounted. The IC chip mounting region 53 is provided on the main-surface-side build-up layer 31. The resin insulation layers 33 and 35 respectively have via conductors 43 and 47 formed therein. The via conductors 43 and 47 electrically connect the conductor layers 42 and the terminal pads 44.

As shown in FIG. 1, the back-surface-side build-up layer 32 has almost the same structure as the aforementioned main-surface-side build-up layer 31. Specifically, the back-surface-side build-up layer 32 has a structure including two resin insulation layers 34 and 36 formed of a thermosetting resin (epoxy resin), and conductor layers 42, wherein the resin insulation layers 34 and 36 and the conductor layers 42 are alternately stacked. Each of the resin insulation layers 34 and 36 exhibits a thermal expansion coefficient of about 10 to about 60 ppm/° C. (specifically about 30 ppm/° C.).

As shown in FIGS. 1 to 3, a plurality of first pads 61, each having a circular shape in plan view, are arranged in a matrix form on the substrate back surface 13 of the wiring substrate 10 (i.e., on the lower surface of the resin insulation layer (second layer) 36). The respective first pads 61 are electrically connected to the conductor layers 42 by the mediation of the via conductors 43. As shown in FIG. 3, in the present embodiment, the diameter A1 of each first pad 61 is 300 μm to 700 μm, which is greater than the diameter of the via conductor 43 (50 μm to 100 μm). In the present embodiment, the thickness A2 of each first pad 61 is 10 μm to 30 μm.

As shown in FIGS. 1 to 3, first protrusions 71, each having a circular shape in plan view, are fixed to center portions of the lower surfaces 62 of the respective first pads 61. The first protrusions 71 are formed separately from the first pads 61. A plurality of first protrusions 71 are provided on the side toward the substrate back surface 13, and each first pad 61 has thereon one first protrusion 71. That is, the number of the first protrusions 71 is equal to that of the first pads 61. As in the case of the first pads 61, the first protrusions 71 are copper posts formed mainly of copper (i.e., electrically conductive material).

As shown in FIG. 3, each first protrusion 71 has an end surface 72 and a peripheral surface 73, and has a generally rectangular shape in cross section. The first protrusion 71 has a rounded edge between the end surface 72 and the peripheral surface 73. In the present embodiment, the diameter A3 of each first protrusion 71 is 200 μm to 600 μm, which is smaller than the diameter A1 of the first pad 61 (300 μm to 700 μm). In the present embodiment, the height A4 of the end surface 72 of the first protrusion 71, as measured from the lower surface 62 of the first pad 61, is 15 μm to 35 μm, which is greater than the thickness A2 of the first pad (10 μm to 30 μm). The central axis of the first protrusion 71 coincides with the central axis C1 of the first pad 61. As used herein, “central axis C1” refers to an axis penetrating the center (in plan view) of the first pad 61.

A portion of the surface (lower surface 62) of the first pad 61, and the surfaces (end surface 72 and peripheral surface 73) of the first protrusion 71 are continuously covered with a plating layer 74. The plating layer 74 is formed of a nickel layer, a palladium layer, and a gold layer. The nickel layer is a plating layer formed through coating of a portion of the surface of the first pad 61 and the surfaces of the first protrusion 71 by electroless nickel plating. The palladium layer is a plating layer formed through coating of the surface of the nickel layer by electroless palladium plating. The gold layer is a plating layer formed through coating of the surface of the nickel layer by electroless gold plating. The first protrusion 71 is connected directly to the first pad 61 without the mediation of, for example, a plating layer. In the present embodiment, the plating layer 74 has a structure including a nickel layer, a palladium layer, and a gold layer. However, the structure of the plating layer may be appropriately modified.

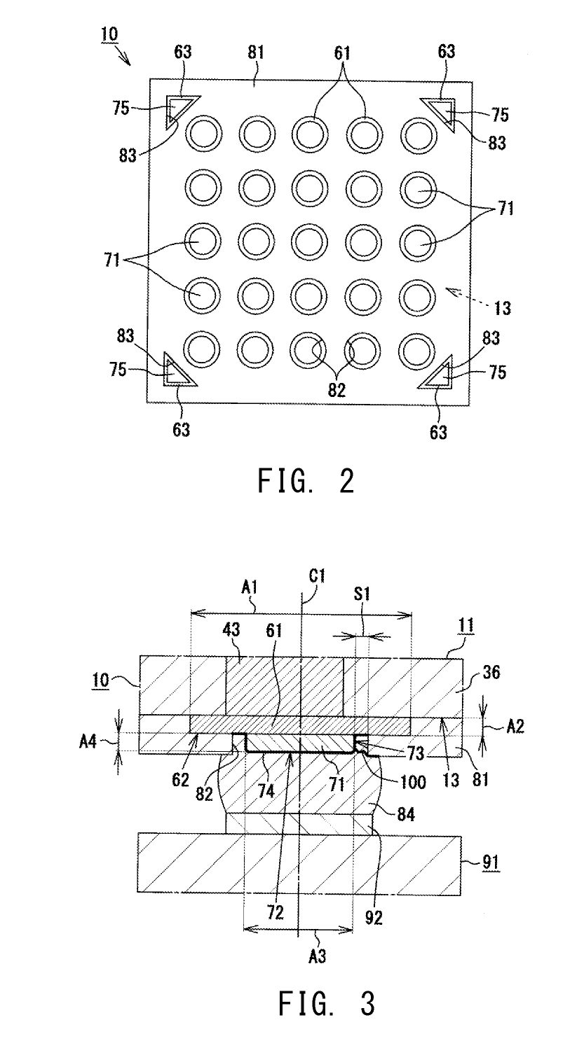

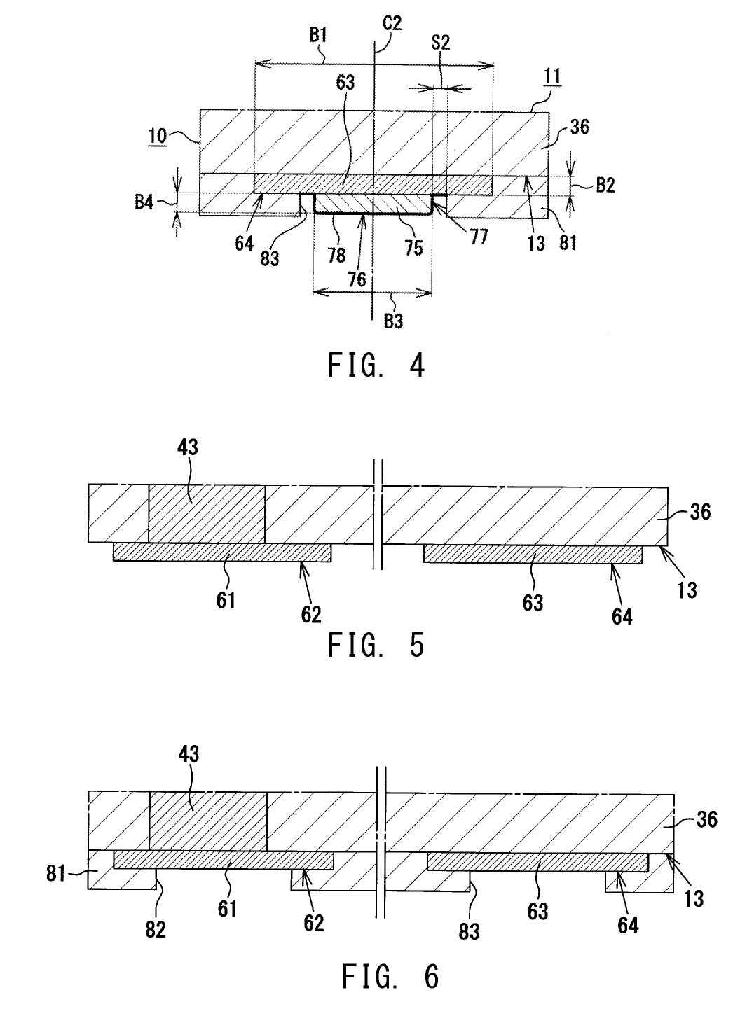

As shown in FIGS. 2 and 4, second pads 63, each having a triangular shape in plan view, are provided at the periphery (four corners) of the substrate back surface 13 of the wiring substrate 10. As shown in FIG. 4, in the present embodiment, the size B1 (maximum size) of each second pad 63 is 400 μm to 800 μm, which is greater than the diameter A1 of each first pad 61 (300 μm to 700 μm). In the present embodiment, the thickness B2 of each second pad 63 is 10 μm to 30 μm.

As shown in FIGS. 2 and 4, second protrusions 75, each having a triangular shape in plan view, are fixed to center portions of the lower surfaces 64 of the respective second pads 63. The second protrusions 75 are formed separately from the second pads 63. A plurality of second protrusions 75 are provided on the side toward the substrate back surface 13, and each second pad 63 has thereon one second protrusion 75. That is, the number of the second protrusions 75 is equal to that of the second pads 63. As in the case of the second pads 63, the second protrusions 75 are copper posts formed mainly of copper (i.e., electrically conductive material).

As shown in FIG. 4, each second protrusion 75 has an end surface 76 and a peripheral surface 77, and has a generally rectangular shape in cross section. The second protrusion 75 has a rounded edge between the end surface 76 and the peripheral surface 77. In the present embodiment, the size B3 (maximum size) of each second protrusion 75 is 200 μm to 600 μm, which is smaller than the size B1 of the second pad 63 (400 μm to 800 μm). In the present embodiment, the height B4 of the end surface 76 of the second protrusion 75, as measured from the lower surface 64 of the second pad 63, is 15 μm to 35 μm, which is greater than the thickness B2 of the second pad 63 (10 μm to 30 μm) and is equal to the height A4 of the first protrusion 71. The central axis of the second protrusion 75 coincides with the central axis C2 of the second pad 63. As used herein, “central axis C2” refers to an axis penetrating the center (in plan view) of the second pad 63.

A portion of the surface (lower surface 64) of the second pad 63, and the surfaces (end surface 76 and peripheral surface 77) of the second protrusion 75 are continuously covered with a plating layer 78. The plating layer 78 is formed of a nickel layer, a palladium layer, and a gold layer, and has the same structure as the plating layer 74. The second protrusion 75 is connected directly to the second pad 63 without the mediation of, for example, a plating layer. In the present embodiment, the plating layer 78 has a structure including a nickel layer, a palladium layer, and a gold layer. However, the structure of the plating layer may be appropriately modified.

As shown in FIGS. 1 to 4, the substrate back surface 13 of the wiring substrate 10 (i.e., the lower surface of the resin insulation layer 36) is almost entirely covered with a solder resist 81. The solder resist 81 has a plurality of first openings 82 through which the first pads 61 and the first protrusions 71 are exposed, and a plurality of second openings 83 through which the second pads 63 and the second protrusions 75 are exposed.

Each first opening 82 has a circular shape in plan view, and has a diameter of 300 μm to 700 μm. Therefore, the plan-view shape of the first opening 82 is similar to that of the first protrusion 71. The first protrusion 71 is provided in the first opening 82 such that the peripheral surface 73 faces the inner surface of the first opening 82, and such that the peripheral surface 73 is located near the inner surface of the first opening 82. The gap S1 between the peripheral surface 73 of the first protrusion 71 and the inner surface of the first opening 82 has fixed dimensions (about 50 μm in the present embodiment) over the entire peripheral surface 73. The height A4 of the first protrusion 71 is 15 μm to 35 μm, which is smaller than the depth of the first opening 82 (20 μm to 40 μm in the present embodiment).

As shown in FIGS. 2 and 4, each second opening 83 has a triangular shape in plan view, and has a size (maximum size) of 400 μm to 800 μm. Therefore, the plan-view shape of the second opening 83 is similar to that of the second protrusion 75. The second protrusion 75 is provided in the second opening 83 such that the peripheral surface 77 faces the inner surface of the second opening 83, and such that the peripheral surface 77 is located near the inner surface of the second opening 83. The gap S2 between the peripheral surface 77 of the second protrusion 75 and the inner surface of the second opening 83 has fixed dimensions (about 50 μm in the present embodiment) over the entire peripheral surface 77. The height B4 of the second protrusion 75 is 15 μm to 35 μm, which is smaller than the depth of the second opening 83 (20 μm to 40 μm in the present embodiment).

Among the protrusions 71 and 75, each first protrusion 71 is employed for connection of a motherboard 91, and each second protrusion 75 serves as an alignment mark. The plan-view shape of the second protrusion 75 (triangular shape in the present embodiment) differs from the plan-view shape of the first protrusion 71 (circular shape in the present embodiment). This alignment mark is recognized through detection, by means of a non-illustrated detector, of the peripheral edge of the end surface 72 of the second protrusion 75 or the edge of the first opening 82.

As shown in FIGS. 1 and 3, solder bumps 84 employed for connection of a motherboard 91 are formed on the surfaces of the first pads 61. Specifically, each solder bump 84 is formed on the surfaces (end surface 72 and peripheral surface 73) of the first protrusion 71 provided in each first opening 82. The solder bump 84 covers a portion of the lower surface 62 of the first pad 61 exposed through the first opening 82, and also covers the entire surfaces of the first protrusion 71. Therefore, the first pad 61 and the first protrusion 71, which are covered with the solder bump 84, are not visually observed. In the present embodiment, the height of each solder bump 84 is 300 μm to 700 μm, which is greater than the height A4 of the first protrusion 71 (15 μm to 35 μm). In the present embodiment, the solder bumps 84 are formed of an Sn—Ag solder (i.e., a lead-free solder). As shown in FIG. 3, each first pad 61 is connected to a terminal 92 of the motherboard 91 by the mediation of the solder bump 84. That is, the solder bump 84 is a so-called BGA bump employed for electrical connection of the wiring substrate to the terminal 92 of the motherboard 91.

Next will be described a method for producing the wiring substrate 10.

Firstly, a step of providing the substrate main body 11 is carried out. Specifically, there is provided a copper-clad laminate prepared by attaching copper foils on opposite surfaces of a glass epoxy substrate. Subsequently, through holes penetrating the copper-clad laminate (including the front and back surfaces thereof) are provided at specific positions through drilling by means of a drill. Then, electroless copper plating and electrolytic copper plating are carried out on the inner surfaces of the through holes of the copper-clad laminate, to thereby form through hole conductors 24 in the through holes. Thereafter, a hollow portion of each through hole conductor 24 is filled with an insulation resin material (epoxy resin), to thereby form a blocking body 25.

Next, a copper plating layer is formed on the copper-clad laminate (including an exposed portion of the blocking body 25) through electroless copper plating and electrolytic copper plating, and then the copper plating layer and the copper foil are subjected to patterning through, for example, the subtractive process, to thereby produce an intermediate product of a core substrate 21 having conductor layers 41 and the through hole conductors 24. The intermediate product of the core substrate 21 is a multi-piece core substrate in which a plurality of regions, each corresponding to the core substrate 21, are arranged in a matrix form in a planar direction.

Subsequently, a main-surface-side build-up layer 31 is formed on the core main surface 22 of the core substrate 21, and a back-surface-side build-up layer 32 is formed on the core back surface 23 of the core substrate 21. Specifically, firstly, a thermosetting epoxy resin is applied onto the core main surface 22 of the core substrate, to thereby form a resin insulation layer 33. Meanwhile, a thermosetting epoxy resin is applied onto the core back surface 23 of the core substrate, to thereby form a resin insulation layer 34. Instead of a thermosetting epoxy resin, a photosensitive epoxy resin, an insulation resin, or a liquid crystalline polymer (LCP) may be applied onto the front or back surface of the core substrate.

Then, laser drilling is carried out by means of a YAG laser or a carbon dioxide gas laser, to thereby provide via holes at positions where via conductors 47 are to be formed. Specifically, via holes penetrating the resin insulation layer 33 are provided so that the surface of the conductor layer 41 is exposed through the via holes. Also, via holes penetrating the resin insulation layer 34 are provided so that the surface of the conductor layer 41 is exposed through the via holes. Next, electrolytic copper plating is carried out according to a conventionally known technique, to thereby form via conductors 47 in the via holes, and to form conductor layers 42 on the resin insulation layers 33 and 34.

Subsequently, a thermosetting epoxy resin is applied onto the resin insulation layers 33 and 34, to thereby form resin insulation layers 35 and 36. Instead of a thermosetting epoxy resin, a photosensitive epoxy resin, an insulation resin, or a liquid crystalline polymer may be applied onto the resin insulation layers 33 and 34. In this case, by means of a laser processing machine or the like, via holes are provided at positions of the resin insulation layer 35 where via conductors 43 are to be formed. Next, electrolytic copper plating is carried out according to a conventionally known technique, to thereby form via conductors 43 in the via holes of the resin insulation layer 35, and to form terminal pads 44 on the resin insulation layer 35. At this point in time, the substrate main body 11 is completed.

In the subsequent pad formation step, plating is carried out on the resin insulation layer 36 (outermost layer) having the substrate back surface 13, to thereby form pads 61 and 63 on the substrate back surface 13 (see FIG. 5). In the present embodiment, the pads 61 and 63 are formed, through pattering, on the resin insulation layer 36 by the semi-additive method. Specifically, firstly, via holes are provided at specific positions of the resin insulation layer 36 through laser processing, and then a desmear step is carried out for removing smears from each via hole. Subsequently, the surface of the resin insulation layer 36 is subjected to electroless copper plating, and then a dry film is laminated on the resin insulation layer 36, to thereby form a first plating resist (not illustrated). Next, laser processing is carried out on the first plating resist layer by means of a laser processing machine. Thus, first openings having a diameter greater than that of the via holes in the resin insulation layer 36 are provided so as to communicate with the via holes, and second openings are provided so as not to communicate with the via holes in the resin insulation layer 36. Then, electrolytic copper plating is carried out, to thereby form via conductors 43 in the respective via holes, and to form first pads 61 on the surface of the resin insulation layer 36 (the substrate back surface 13) exposed through the first openings, and on the surfaces of the via conductors 43 exposed through the first openings. The first pads 61 are formed mainly of copper (copper layer). Also, second pads 63 formed mainly of copper (copper layer) are provided on the surface of the resin insulation layer 36 (the substrate back surface 13) exposed through the second openings. Thereafter, the first plating resist is removed, and unnecessary electroless copper plating layer is also removed. In the present embodiment, the thickness of the copper layer is 10 μm to 30 μm. In the present embodiment, the copper layer is formed through plating. However, the copper layer may be formed through another technique such as sputtering or CVD. Preferably, the copper layer is formed through plating in order to achieve a height required particularly for the copper layer (i.e., 10 μm to 30 μm).

In the subsequent solder resist formation step, a photosensitive epoxy resin is applied onto the resin insulation layer 36 having the pads 61 and 63, followed by curing, to thereby form a solder resist 81 covering the substrate back surface 13 (see FIG. 6). Next, the solder resist 81 is subjected to light exposure and development via a specific mask provided on the solder resist 81, to thereby provide openings 82 and 83 through patterning (see FIG. 6).

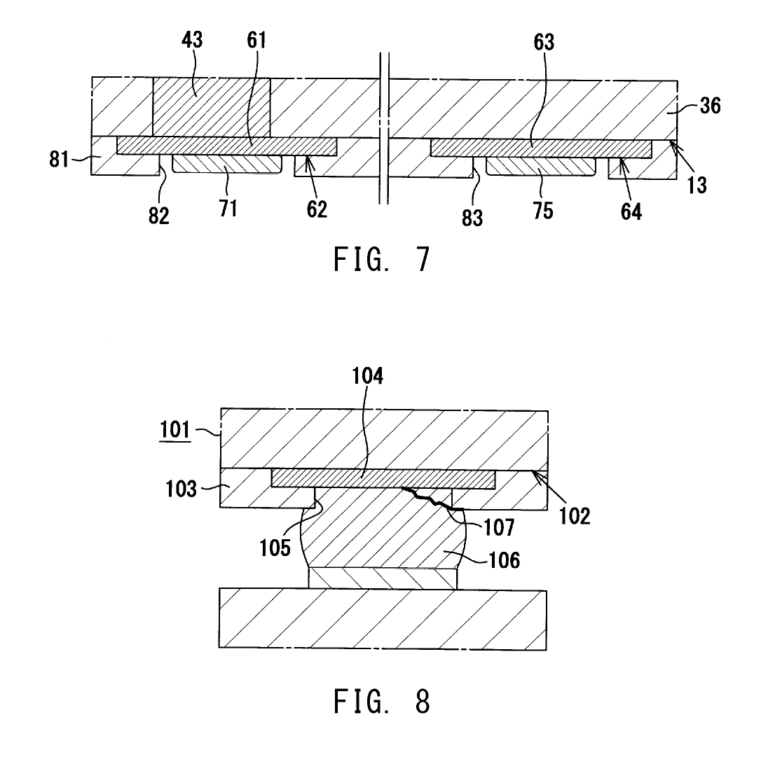

In the subsequent protrusion formation step, plating is carried out on the pads 61 and 63, to thereby form protrusions 71 and 75 on the lower surfaces 62 and 64 of the pads 61 and 63, respectively (see FIG. 7). Specifically, firstly, dry film is laminated on the solder resist 81, to thereby form a second plating resist (not illustrated). Next, laser processing is carried out on the second plating resist by means of a laser processing machine, to thereby provide openings through which center portions of the lower surfaces 62 and 64 of the pads 61 and 63 are exposed. Then, electrolytic copper plating is carried out on the center portions of the lower surfaces 62 and 64 exposed through the openings. At this point in time, the protrusions 71 and 75 formed mainly of copper (copper layer) are provided. Thereafter, the second plating resist is removed. Each of the copper layers forming the protrusions 71 and 75 has a thickness of 15 μm to 35 μm. In the present embodiment, the copper layer is formed through electrolytic plating. However, the copper layer may be formed through another technique such as electroless plating, sputtering, or CVD. Preferably, the copper layer is formed through plating in order to achieve a height required particularly for the copper layer (i.e., 15 μm to 35 μm).

Thereafter, electroless nickel plating is carried out, to thereby form a nickel layer on the surfaces (lower surfaces 62 and 64) of the pads 61 and 63, and on the surfaces (end surfaces 72 and 76 and peripheral surfaces 73 and 77) of the protrusions 71 and 75. Subsequently, electroless palladium plating is carried out, to thereby form a palladium layer on the nickel layer. Then, electroless gold plating is carried out, to thereby form a gold layer on the palladium layer. Each of the nickel layer, the palladium layer, and the gold layer has a thickness of 0.01 μm to 15 μm. In the present embodiment, each of the nickel layer, the palladium layer, and the gold layer is formed through plating. However, each of these layers may be formed through another technique such as sputtering or CVD.

In the subsequent solder bump formation step, solder bumps 84 are formed on the first pads 61 provided on the substrate back surface 13 of the wiring substrate 10. Specifically, solder balls are mounted on the first pads 61 by means of a non-illustrated solder ball mounting apparatus, and then the solder balls are heat-melted (reflowed) at a specific temperature, to thereby form solder bumps 84 on the first pads 61. Meanwhile, solder bumps 45 are formed on the terminal pads 44 provided on the substrate main surface 12 of the wiring substrate 10. Specifically, solder balls are mounted on the terminal pads 44 by means of a solder ball mounting apparatus, and then the solder balls are heat-melted (reflowed) at a specific temperature, to thereby form solder bumps 45 on the terminal pads 44. At this point in time, an intermediate product of the wiring substrate 10 is completed.

Thereafter, the intermediate product of the wiring substrate 10 is divided into pieces by means of, for example, a conventional well-known cutting apparatus. Thus, product units of the intermediate product are divided into individual pieces; i.e., a plurality of wiring substrates 10 are produced simultaneously (see FIG. 1).

Subsequently, an IC chip mounting step is carried out. Specifically, firstly, an IC chip 51 is placed on the side toward the substrate main surface 12 of the wiring substrate 10 so that surface connection terminals 52 provided on the bottom surface of the IC chip 51 are placed on the solder bumps 45 arranged on the wiring substrate 10. Then, the solder bumps 45 are heat-melted (reflowed) at a temperature of about 230° C. to about 260° C., whereby the terminal pads 44 are flip-chip connected to the surface connection terminals 52, and the IC chip 51 is mounted on the wiring substrate 10 (see FIG. 1).

Therefore, the present embodiment can yield the following effects.

(1) In the wiring substrate 10 of the present embodiment, even if cracking 100 (see FIG. 3) occurs in the solder bump 84, and the cracking 100 proceeds along the interface between the solder bump 84 and the first pad 61, progress of the cracking 100 is reliably suppressed when it reaches the first protrusion 71. Therefore, breakage of an electrical path formed of the solder bump 84 can be prevented, and the thus-produced wiring substrate 10 exhibits improved reliability.

(2) In the present embodiment, the first protrusion 71 is fixed to a portion of the lower surface 62 of the first pad 61; i.e., the corresponding portion generally assumes a convex form. Thus, when the solder bump 84 is formed so as to cover the surface (lower surface 62) of the first pad 61 and the surfaces (end surface 72 and peripheral surface 73) of the first protrusion 71, the first protrusion 71 is fitted into the solder bump 84. Therefore, a specific contact area is secured between the solder bump 84 and the first pad 61 and the first protrusion 71. Thus, adhesion strength can be enhanced between the surface of the first pad 61 and the solder bump 84, and between the surfaces of the first protrusion 71 and the solder bump 84, which results in prevention of defective connection between the individual first pads 61 and the motherboard 91. That is, since the wiring substrate 10 has the first pad 61 and the first protrusion 71, which are suitable for connection of the motherboard 91, the wiring substrate 10 exhibits further improved reliability.

(3) In the present embodiment, the height A4 of the end surface 72 of the first protrusion 71, as measured from the lower surface 62 of the first pad 61, is smaller than the depth of the first opening 82. Therefore, in the solder bump formation step, a solder ball to become the solder bump 84 can be reliably placed in the first opening 82.

The present embodiment may be modified as follows.
In the aforementioned embodiment, the plan-view shape (circular shape) of the first protrusion 71 employed for connection of the motherboard 91 differs from the plan-view shape (triangular shape) of the second protrusion 75 serving as an alignment mark. However, the protrusions 71 and 75 may have the same plan-view shape.
In the aforementioned embodiment, each pad 61 or 63 has thereon one protrusion 71 or 75, respectively. However, the present invention is not limited thereto, and two or more protrusions may be formed on each pad.
In the aforementioned embodiment, each of the protrusions 71 and 75 is a conductor (copper post) formed through copper plating. However, the protrusion may be a conductor formed through printing of a copper paste.
In the aforementioned embodiment, each of the plating layers 74 and 78, which respectively cover the pads 61 and 63 and the protrusions 71 and 75, is a plating layer formed of a nickel layer, a palladium layer, and a gold layer. However, the plating layer 74 or 78 may be replaced with another plating layer formed of, for example, a nickel layer and a gold layer, so long as the plating layer does not include a copper layer.
In the solder bump formation step according to the aforementioned embodiment, the solder bump 84 is formed through heat-melting (reflow) of a solder ball provided on the first pad 61. However, the solder bump may be formed through heat-melting of a solder paste applied through printing onto the first pad 61.

Next will be enumerated technical ideas that can be grasped from the above-described embodiment.

(1) The wiring substrate described in means 1 is characterized in that at least a portion of the surface of the pad, and the end surface and peripheral surface of the protrusion are continuously covered with a plating layer, and the protrusion is connected directly to the surface of the pad without the mediation of the plating layer.

(2) The wiring substrate described in means 1 is characterized in that a plurality of protrusions are provided on the side toward the substrate back surface of the substrate main body; at least some of the protrusions serve as alignment marks; and the protrusions serving as alignment marks are located at the periphery of the substrate back surface.

(3) A method for producing the wiring substrate described in means 1, characterized by comprising a step of providing a substrate main body; a step of forming a plurality of pads on the substrate back surface of the substrate main body; a step of forming a solder resist so as to cover the substrate back surface; and a step of forming a protrusion on a portion of the surface of each of the pads.

### DESCRIPTION OF REFERENCE NUMERALS

10: wiring substrate
11: substrate main body
12: substrate main surface
13: substrate back surface
61: first pad
62, 64: surface (lower surface) of pad
63: second pad
71: first protrusion
72, 76: end surface of protrusion
73, 77: peripheral surface of protrusion
74, 78: plating layer
75: second protrusion
81: solder resist
82: first opening
83: second opening
84: solder bump
91: motherboard
A4, B4: height between pad surface and end surface
S1, S2: gap between peripheral surface of protrusion and inner surface of opening

What is claimed is:

1. A wiring substrate comprising:
a substrate main body having a substrate main surface and a substrate back surface;
a plurality of pads provided on the substrate back surface of the substrate main body, and having surfaces on which solder bumps employed for connection of the wiring substrate to a motherboard can be formed; and
a solder resist covering the substrate back surface of the substrate main body, and having a plurality of openings through which the pads are exposed, the wiring substrate being characterized in that
each of the pads has, on a portion of the surface thereof, a protrusion having an end surface and a peripheral surface;
the end surface of the protrusion has a height as measured from the surface of the pad, the height being smaller than the depth of each of the openings;
the protrusion is provided in the opening such that the peripheral surface faces an inner surface of the opening; and
the protrusion has a plan-view shape similar to that of the opening.

2. A wiring substrate according to claim 1, wherein the protrusion is provided in the opening such that the peripheral surface of the protrusion is located near the inner surface of the opening.

3. A wiring substrate according to claim 1, wherein the gap between the peripheral surface of the protrusion and the inner surface of the opening has fixed dimensions over the entire peripheral surface.

4. A wiring substrate according to claim 1, wherein the protrusion has a rounded edge between the end surface and the peripheral surface.

5. A wiring substrate according to claim 1, wherein at least a portion of the surface of the pad, and the end surface and the peripheral surface of the protrusion are continuously covered with a plating layer.

6. A wiring substrate according to claim 1, wherein a plurality of protrusions are provided on the side toward the substrate back surface of the substrate main body, and at least some of the protrusions serve as an alignment mark.

7. A wiring substrate according to claim 6, wherein the alignment mark has a plan-view shape different from that of the protrusion for connection of a motherboard.

8. A wiring substrate according to claim 1, wherein a solder bump is formed on the surface of a protrusion provided in at least one opening of the plurality of openings.
